(19) United States
(12) Patent Application Publication
(10) Pub. No.: US 2022/0084813 A1
(43) Pub. Date: Mar. 17, 2022

(54) METHOD OF MANUFACTURING SEMICONDUCTOR DEVICE AND SUBSTRATE PROCESSING APPARATUS

(71) Applicant: Kioxia Corporation, Tokyo (JP)

(72) Inventors: Makoto IYAMA, Yokkaichi (JP); Fumito SHOJI, Yokkaichi (JP); Masatoshi SHOMURA, Mie (JP)

(73) Assignee: Kioxia Corporation, Tokyo (JP)

(21) Appl. No.: 17/199,510

(22) Filed: Mar. 12, 2021

(30) Foreign Application Priority Data
Sep. 11, 2020 (JP) 2020-152917
Dec. 4, 2020 (JP) 2020-201582

(51) Int. Cl. H01L 21/02; H01L 21/67; C25D 5/22; C25D 21/04; C25F 1/00

(52) U.S. Cl. CPC H01L 21/02068; H01L 21/6723; C25F 1/00; C25D 5/22; C25D 21/04; H01L 21/67028

(57) ABSTRACT

According to one embodiment, a method of manufacturing a semiconductor device includes loading a substrate into a processing container, airtightly sealing the processing container in which the substrate has been loaded, reducing a pressure of the processing container airtightly sealed, supplying a processing solution into the processing container with reduced pressure, performing a process on the substrate using the processing solution, discharging the processing solution used for the process from the processing container, after discharging the processing solution, opening the processing container, and unloading the substrate subjected to the process out of the processing container.

### CROSS-REFERENCE TO RELATED APPLICATIONS

This application is based upon and claims the benefit of priority from Japanese Patent Application No. 2020-152917, filed on Sep. 11, 2020 and Japanese Patent Application No. 2020-201582, filed on Dec. 4, 2020; the entire contents of which are incorporated herein by reference.

### FIELD

Embodiments described herein relate generally to a method of manufacturing a semiconductor device and a substrate processing apparatus.

### BACKGROUND

In the manufacturing process of a semiconductor device, in some cases, a substrate is housed in a processing container of a substrate processing apparatus, and a processing solution such as a plating solution or a cleaning solution is supplied to perform a predetermined process on the substrate. However, when the substrate is loaded into and unloaded out of the processing container, the processing solution may be exposed to an atmospheric air and degenerate.

### BRIEF DESCRIPTION OF THE DRAWINGS

FIG. 1 is a diagram illustrating an example of a configuration of a substrate processing apparatus according to an embodiment;

FIGS. 2A to 2D are schematic views illustrating operations from a wafer loading operation to a rinse solution discharge operation, these operations being performed by the substrate processing apparatus according to the embodiment;

FIG. 3A to 3C are schematic views illustrating a wafer plating process performed by the substrate processing apparatus according to the embodiment;

FIGS. 4A to 4D are schematic views illustrating operations from a post-cleaning process to a wafer loading operation, these operations being performed by the substrate processing apparatus according to the embodiment;

FIGS. 5A and 5B are schematic views illustrating a state where a metal film is formed on the wafer by the plating process performed by the substrate processing apparatus of the embodiment;

FIG. 6 is a flow chart illustrating an example of a procedure of the plating process in the substrate processing apparatus according to the embodiment; and

FIG. 7 is a diagram illustrating an example of a more detailed configuration of the substrate processing apparatus 1 according to the embodiment.

### DETAILED DESCRIPTION

According to one embodiment, a method of manufacturing a semiconductor device includes loading a substrate into a processing container, airtightly sealing the processing container in which the substrate has been loaded, reducing a pressure of the processing container airtightly sealed, supplying a processing solution into the processing container with reduced pressure, performing a process on the substrate using the processing solution, discharging the processing solution used for the process from the processing container, after discharging the processing solution, opening the processing container, and unloading the substrate subjected to the process out of the processing container.

Hereinafter, the present invention will be explained in detail with reference to the drawings. The present invention is not limited to the following embodiment. In addition, the components in the following embodiment include components that can be easily assumed by those skilled in the art or substantially same components.

(Example of Configuration of Substrate Processing Apparatus)

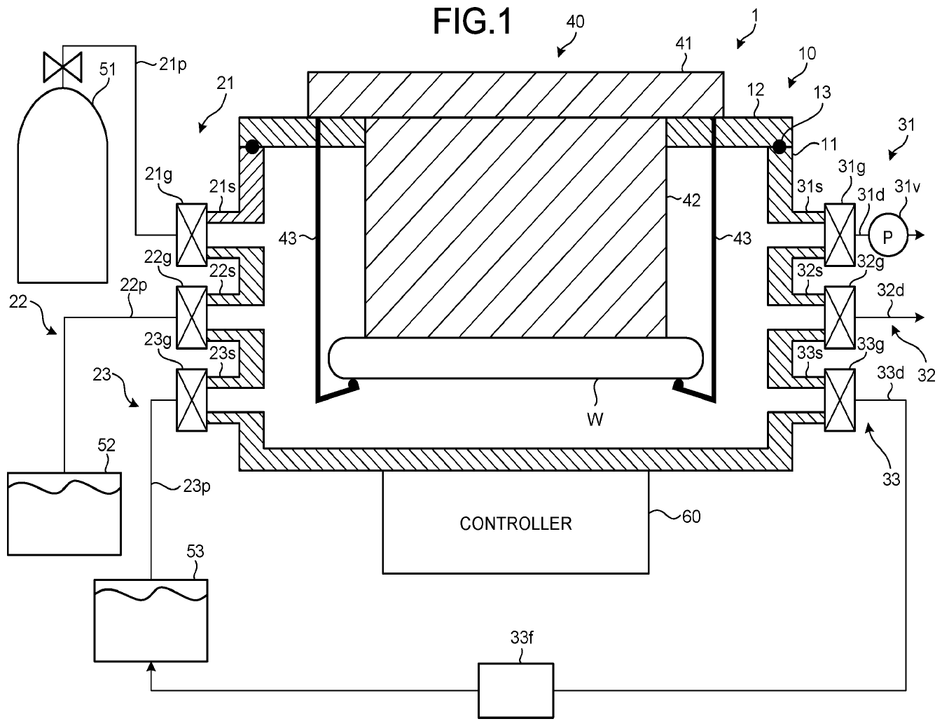

FIG. 1 is a diagram illustrating an example of a configuration of a substrate processing apparatus 1 according to an embodiment. As illustrated in FIG. 1, the substrate processing apparatus 1 includes a processing container 10, a nitrogen gas supply unit 21, an ion-exchange water supply unit 22, a plating solution supply unit 23, an exhaust unit 31, an ion-exchange water discharge unit 32, a plating solution discharge unit 33, a wafer holding unit 40, and a controller 60.

The processing container 10 includes a wafer housing unit 11 and a top plate 12. The wafer housing unit 11 as a substrate housing unit has a box shape with the top open, and is configured to be capable of housing a wafer W as a substrate. The top plate 12 as a lid is a plate-like member configured to close an opening at the top of the wafer housing unit 11. An O-ring 13 as a sealing unit is interposed in a portion where the wafer housing unit 11 and the top plate 12 come into contact with each other. The processing container 10 can thus be airtightly sealed.

The processing container 10 is connected to the nitrogen gas supply unit 21, the ion-exchange water supply unit 22, and the plating solution supply unit 23. The nitrogen gas supply unit 21, the ion-exchange water supply unit 22, and the plating solution supply unit 23 are each arranged on one side surface of the processing container 10, for example.

The nitrogen gas supply unit 21 as an inert gas supply unit includes a supply port 21s, a gate valve 21g, and a supply pipe 21p. The supply port 21s is an opening provided in the processing container 10.

The gate valve 21g as a first valve is connected to an end of the supply port 219s extending from the processing container 10. When the gate valve 21g is opened and closed, the supply of a nitrogen gas into the processing container 10 is started and stopped.

One end of the supply pipe 21p is connected to the side of the gate valve 21g opposite to the side connected to the supply port 21s. The other end of the supply pipe 21p is connected to a gas cylinder 51 as an inert gas supply source in which a nitrogen gas as an inert gas is stored, for example.

With the above configuration, the nitrogen gas supply unit 21 is configured to be capable of supplying a nitrogen gas into the processing container 10. However, the nitrogen gas may be another inert gas such as a noble gas. Alternatively, the nitrogen gas supply unit 21 may be configured to be capable of appropriately switching and supplying a plurality of types of inert gases such as a nitrogen gas and a noble gas.

The ion-exchange water supply unit 22 as a rinse solution supply unit includes a supply port 22s, a gate valve 22g, and a supply pipe 22p. The supply port 22s is an opening provided in the processing container 10.

The gate valve 22g as a second valve is connected to an end of the supply port 22s extending from the processing container 10. When the gate valve 22g is opened and closed, the supply of ion exchange water into the processing container 10 is started and stopped.

One end of the supply pipe 22p is connected to the side of the gate valve 22g opposite to the side connected to the supply port 22s. The other end of the supply pipe 22p is connected to a tank 52 as a rinse solution supply source in which ion exchange water (DI Water: De-Ionization Water) as a rinse solution is stored.

With the above configuration, the ion-exchange water supply unit 22 is configured to be capable of supplying ion exchange water into the processing container 10.

The plating solution supply unit 23 as a processing solution supply unit includes a supply port 23s, a gate valve 23g, and a supply pipe 23p. The supply port 23s is an opening provided in the processing container 10.

The gate valve 23g as a third valve is connected to an end of the supply port 23s extending from the processing container 10. When the gate valve 23g is opened and closed, the supply of a plating solution into the processing container 10 is started and stopped.

One end of the supply pipe 23p is connected to the side of the gate valve 23g opposite to the side connected to the supply port 23s. The other end of the supply pipe 23p is connected to a tank 53 as a processing solution supply source in which a plating solution as a processing solution is stored.

With the above configuration, the plating solution supply unit 23 is configured to be capable of supplying a plating solution into the processing container 10. By using various plating solutions such as a copper plating solution, a nickel plating solution, and a gold plating solution, various metal films such as copper, nickel, and gold are formed on the wafer W.

The processing container 10 is connected to the exhaust unit 31, the ion-exchange water discharge unit 32, and the plating solution discharge unit 33. The exhaust unit 31, the ion-exchange water discharge unit 32, and the plating solution discharge unit 33 are each arranged on one side surface of the processing container 10, for example, the side surface facing the side surface on which the nitrogen gas supply unit 21 and the like described above are arranged.

The exhaust unit 31 includes an exhaust port 31s, a gate valve 31g, an exhaust pipe 31d, and a pump 31v. The exhaust port 31s is an opening provided in the processing container 10.

The gate valve 31g as a fourth valve is connected to an end of the exhaust port 31s extending from the processing container 10. When the gate valve 31g is opened and closed, the exhaust of atmosphere in the processing container 10, such as a nitrogen gas or an atmospheric air, is started and stopped.

One end of the exhaust pipe 31d is connected to the side of the gate valve 31g opposite to the side connected to the exhaust port 31s. The exhaust pipe 31d includes the pump 31v, and the other end of the exhaust pipe 31d extends to the outside of the substrate processing apparatus 1.

With the above configuration, the exhaust unit 31 is configured to be capable of exhausting the atmosphere in the processing container 10. That is, by opening the gate valve 31g while the pump 31v is kept operating, the atmosphere in the processing container 10 is exhausted to the outside of the substrate processing apparatus 1.

The ion-exchange water discharge unit 32 as a rinse solution discharge unit includes a discharge port 32s, a gate valve 32g, and a discharge pipe 32d. The exhaust port 32s is an opening provided in the processing container 10.

The gate valve 32g as a fifth valve is connected to an end of the discharge port 32s extending from the processing container 10. When the gate valve 32g is opened and closed, the discharge of ion exchange water in the processing container 10 is started and stopped.

One end of the discharge pipe 32d is connected to the side of the gate valve 32g opposite to the side connected to the discharge port 32s. The other end of the discharge pipe 32d extends to the outside of the substrate processing apparatus 1.

With the above configuration, the ion-exchange water discharge unit 32 is configured to be capable of discharging ion exchange water from the processing container 10 to the outside of the substrate processing apparatus 1.

The plating solution discharge unit 33 as a processing solution discharge unit includes a discharge port 33s, a gate valve 33g, and a discharge pipe 33d. The discharge port 33s is an opening provided in the processing container 10.

The gate valve 33g as a sixth valve is connected to an end of the discharge port 33s extending from the processing container 10. When the gate valve 33g is opened and closed, the discharge of a plating solution in the processing container 10 is started and stopped.

One end of the discharge pipe 33d is connected to the side of the gate valve 33g opposite to the side connected to the discharge port 33s. The discharge pipe 33d includes a circulation unit 33f, and the other end of the discharge pipe 33d is connected to the tank 53 in which the plating solution described above is stored. The circulation unit 33f is configured to purify the plating solution discharged from the processing container 10 and return the plating solution to the side of the tank 53 again. The function of purifying the plating solution may be achieved by, for example, a filter that removes foreign substances and the like from the plating solution discharged from the processing container 10. The function of returning the plating solution to the tank 53 may be achieved by a pump such as a liquid pump.

Here, the discharge pipe 33d connecting the discharge port 33s to the tank 53 and the supply pipe 23p connecting the tank 53 to the supply port 23s function as a connection pipe connecting the discharge port 33s to the supply port 23s. Further, the discharge pipe 33d, the circulation unit 33f, the tank 53, and the supply pipe 23p function as a circulation mechanism that circulates the plating solution discharged from the discharge port 33s to the supply port 23s, for example.

With the above circulation mechanism, the plating solution discharge unit 33 is configured to be capable of discharging the plating solution from the processing container 10, circulating the plating solution to the tank 53 on the upstream side, and purifying and repeatedly using the plating solution described above.

Meanwhile, the substrate processing apparatus 1 does not need to have a mechanism that circulates ion exchange water, and ion exchange water used for a cleaning process may be discarded each time the ion exchange water is used. Consequently, it is easy to keep the inside of the processing container 10, the plating solution, and the wafer W clean. However, it may be configured that the discharge pipe 32d that discharges ion exchange water includes a pump such as a liquid pump so as to facilitate the discharge of ion exchange water from the processing container 10.

The wafer holding unit 40 as a substrate holding unit includes a base 41, a wafer holding table 42, and a contact ring 43.

The base 41 is arranged above the processing container 10, and includes a rotation mechanism such as a motor (not illustrated) that rotates the wafer holding table 42 and the contact ring 43, and a charge supply mechanism (not illustrated) that supplies charges to the contact ring 43.

The wafer holding table 42 is provided on the lower surface of the base 41. The wafer holding table 42 includes a suction mechanism (not illustrated), and is configured to be capable of holding, on the lower surface, the wafer W whose surface, that is, surface on which a semiconductor device is manufactured, is directed downward.

The contact ring 43 is an annular member that is supported by a support rod extending from the lower surface of the base 41, and is configured to come into contact with the surface of the wafer W held by the wafer holding table 42 with the surface downward. The contact ring 43 is configured to be capable of supplying power to the wafer W by being supplied with charges from the charge supply mechanism provided on the base 41.

Further, the wafer holding unit 40 is configured to be vertically movable while holding the wafer W by a transport mechanism (not illustrated), and is also configured to be capable of loading and unloading the wafer W into and out of the processing container 10.

The controller 60 is configured as a computer that includes, for example, a central processing unit (CPU), a read only memory (ROM), a random access memory (RAM), and the like and that controls the entire substrate processing apparatus 1.

That is, the controller 60 controls the suction mechanism included in the wafer holding table 42 of the wafer holding unit 40 to hold the wafer W on the wafer holding table 42. Further, the controller 60 controls the charge supply mechanism included in the base 41 of the wafer holding unit 40 to supply power to the wafer W via the contact ring 43. Furthermore, the controller 60 controls the motor included in the base 41 of the wafer holding unit 40 to rotate the wafer holding table 42 and the contact ring 43 while the wafer W is held.

Moreover, the controller 60 controls the transport mechanism (not illustrated) to vertically move the wafer holding unit 40 with the wafer W held and load and unload the wafer W into and out of the processing container 10.

Further, the controller 60 controls the gate valve 21g to start and stop the supply of a nitrogen gas into the processing container 10. The controller 60 controls the gate valve 22g to start and stop the supply of ion exchange water into the processing container 10. The controller 60 controls the gate valve 23g to start and stop the supply of a plating solution into the processing container 10.

Further, the controller 60 controls the gate valve 31g and the pump 31v to start and stop the exhaust of atmosphere in the processing container 10. Moreover, the controller 60 controls the gate valve 32g to start and stop the discharge of ion exchange water from the processing container 10. Furthermore, the controller 60 controls the gate valve 33g to start and stop the discharge of a plating solution from the processing container 10.

As described above, the substrate processing apparatus 1 of the embodiment is configured as, for example, an electroplating apparatus that supplies power to the wafer W to perform a plating process. The wafer W subjected to the plating process by the substrate processing apparatus 1 may be, for example, a semiconductor wafer such as a silicon wafer, a compound wafer such as a quartz wafer or a gallium arsenide wafer, or the like. Alternatively, the wafer W may be a bonded wafer in which a plurality of wafers are bonded.

(Example of Operation of Substrate Processing Apparatus)

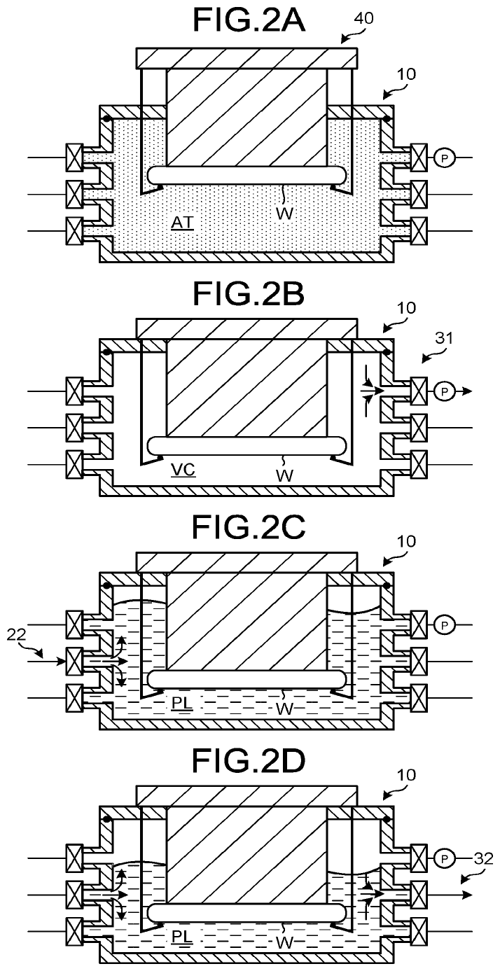

Next, an example of an operation of the substrate processing apparatus 1 of the embodiment will be described with reference to FIGS. 2A to 5B.

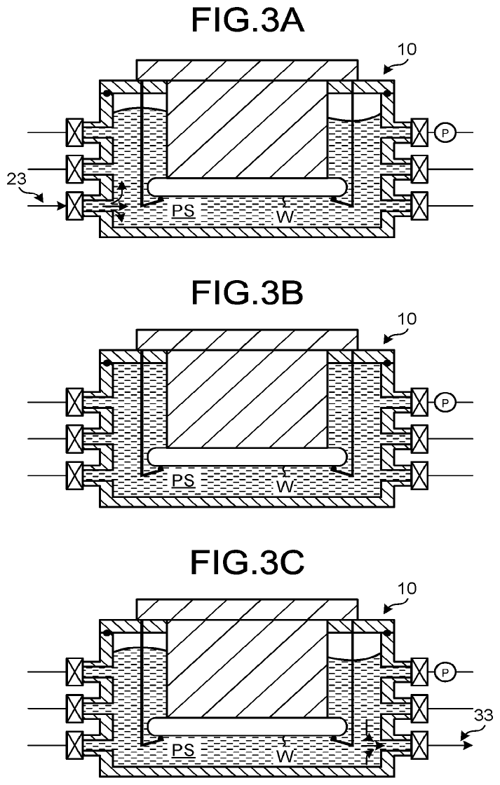

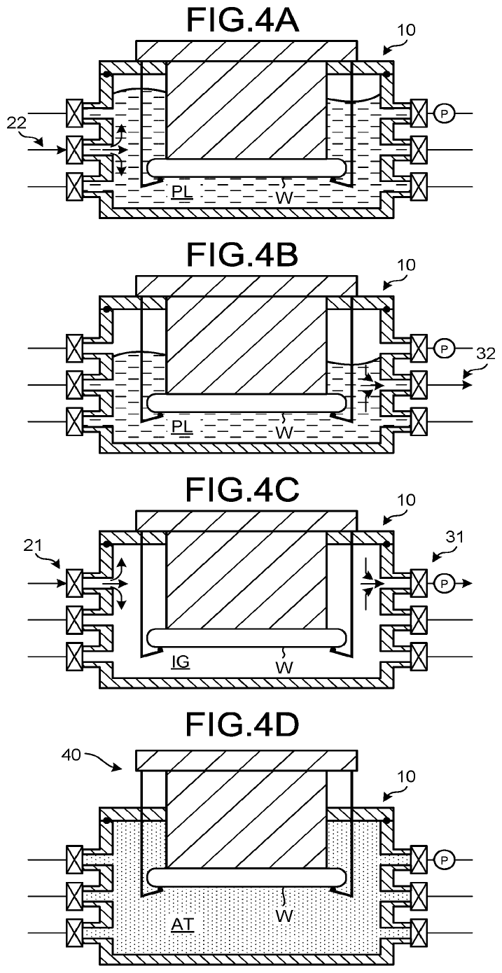

FIGS. 2A to 2D are schematic views illustrating operations from an operation of loading the wafer W to an operation of discharging a rinse solution, these operations being performed by the substrate processing apparatus 1 according to the embodiment. FIGS. 3A to 3C are schematic views illustrating a process of plating the wafer W performed by the substrate processing apparatus 1 according to the embodiment. FIGS. 4A to 4D are schematic views illustrating operations from a post-cleaning process to an operation of unloading the wafer W, these operations being performed by the substrate processing apparatus 1 according to the embodiment.

As illustrated in FIG. 2A, the transport mechanism is driven to move the wafer holding unit 40 holding the wafer W downward and load the wafer W into the processing container 10. Various processes in the manufacturing process of a semiconductor device have been performed on the wafer W, and a part of the semiconductor device (not illustrated) is arranged on the surface of the wafer W that is held by the wafer holding unit 40, the surface being directed downward. When the wafer W is loaded, the processing container 10 is filled with an atmospheric air AT. However, the processing container 10 may be filled with an inert gas such as a nitrogen gas. In addition, various gases can be used as a sealing gas for the processing container 10, as long as the gas is clean. As a result, the number of particles in the processing container 10 can be reduced.

After the wafer W is loaded into the processing container 10, the wafer W starts to be rotated by the wafer holding unit 40. The rotation of the wafer W continues until each process in the processing container 10 is completed. However, it is only required that the rotation of the wafer W starts before the plating process with a plating solution PS starts. For this reason, for example, the rotation of the wafer W can start at any timing such as during or after filling of ion exchange water PL in the processing container 10, which will be described later, or during or after filling of the plating solution PS.

As illustrated in FIG. 2B, with the processing container 10 airtightly sealed, the gate valve 31g of the exhaust unit 31 is opened, the pump 31v is operated, and the atmospheric air AT in the processing container 10 is exhausted, so that the pressure inside the processing container 10 is reduced to, for example, 2.6 kPa or more and 3.3 kPa or less. This is also called degassing in the processing container 10.

As illustrated in FIG. 2C, after the gate valve 31g of the exhaust unit 31 is closed, the gate valve 22g of the ion-exchange water supply unit 22 is opened, and the ion exchange water PL is supplied into the processing container 10 with reduced pressure, so that a pre-cleaning process is performed on the wafer W and the inside of the processing container 10. At this time, the gate valve 32g of the ion-exchange water discharge unit 32 may also be opened continuously or intermittently to replace the ion exchange water PL in the processing container 10 a plurality of times.

As a result, the atmospheric components adsorbed on the surfaces of the wafer W and the processing container 10 and the like are almost completely removed. Further, impurities, foreign substances, and the like are also removed from the wafer W and the inside of the processing container 10. For example, these impurities, foreign substances, and the like adhere to the wafer W itself, or are mixed from the atmospheric air when the wafer W is loaded.

After the inside of the processing container 10 is degassed as described above and before the ion exchange water PL is supplied, an inert gas such as a nitrogen gas may be supplied into the processing container 10 to perform a process of increasing the pressure inside the processing container 10 to be equal to or higher than the atmospheric pressure. The inert gas may be a nitrogen gas or the like supplied by the nitrogen gas supply unit 21. As a result, the atmospheric components, impurities, foreign substances, and the like remaining in the processing container 10 can be more reliably discharged from the processing container 10. Thereafter, the ion exchange water PL is supplied into the processing container 10 while the inert gas is exhausted from the processing container 10. As the inert gas is exhausted from the processing container 10, the pressure inside the processing container 10 decreases, so that the supply rate of the ion exchange water PL into the processing container 10 can be increased.

As illustrated in FIG. 2D, after the gate valve 22g of the ion-exchange water supply unit 22 is closed, the gate valve 32g of the ion-exchange water discharge unit 32 is opened, and the ion exchange water PL is discharged from the processing container 10 in which the pre-cleaning process is completed. At this time, the ion exchange water PL may be discharged while the inert gas is supplied into the processing container 10. The inert gas may be a nitrogen gas or the like supplied by the nitrogen gas supply unit 21. When the nitrogen gas supply unit 21 is configured to be capable of switching and supplying a plurality of types of gases, the inert gas described above may be a dedicated gas or the like for facilitating the discharge of the ion exchange water PL. As a result, the ion exchange water PL is pushed out of the processing container 10 by the inert gas. In addition, the pressure inside the processing container 10 increases with the supply of the inert gas. Consequently, the discharge rate of the ion exchange water PL from the processing container 10 can be increased, and it is possible to inhibit the ion exchange water PL from remaining in the processing container 10.

As illustrated in FIG. 3A, after the gate valve 32g of the ion-exchange water discharge unit 32 is closed, the gate valve 23g of the plating solution supply unit 23 is opened, and the plating solution PS is supplied into the processing container 10 from which the ion exchange water PL has been discharged. The supply of the plating solution PS continues until the processing container 10 is almost completely filled with the plating solution PS.

After the ion exchange water PL is discharged and before the plating solution PS is supplied, a cycle purge process of supplying an inert gas such as a nitrogen gas supplied by the nitrogen gas supply unit 21 into the processing container 10 to increase the pressure inside the processing container 10 to the atmospheric pressure or higher, then exhausting the inert gas, and reducing the pressure inside the processing container 10 may be performed once or a plurality of times. Thereafter, the plating solution PS is supplied into the processing container 10. The supply of the plating solution PS can be started at any timing such as the timing when the pressure inside the processing container 10 is equal to or higher than the atmospheric pressure or the timing when the pressure is reduced. When the plating solution PS is supplied at the timing when the pressure inside the processing container 10 is reduced, the supply rate of the plating solution PS into the processing container 10 can be increased as in the case of the ion exchange water PL, which has been described above.

As illustrated in FIG. 3B, after the gate valve 23g of the plating solution supply unit 23 is closed, power supply to the wafer W starts via the contact ring 43, so that the plating process is performed on the wafer W. As a result, a desired metal film is formed on the wafer W.

As illustrated in FIG. 3C, the gate valve 33g of the plating solution discharge unit 33 is opened, and the plating solution PS is discharged from the processing container 10 in which the plating process is completed. At this time, the discharge of the plating solution PS may be accelerated by the function of circulating the plating solution PS by the circulation unit 33f. More specifically, for example, the discharge of the plating solution PS can be accelerated by operating the pump included in the circulation unit 33f, sucking the plating solution PS discharged from the processing container 10, and facilitating the circulation of the plating solution PS to the tank 53.

In addition, at this time, the plating solution PS may be discharged while the inert gas is supplied into the processing container 10. The inert gas may be a nitrogen gas or the like supplied by the nitrogen gas supply unit 21. When the nitrogen gas supply unit 21 is configured to be capable of switching and supplying a plurality of types of gases, the inert gas described above may be a dedicated gas or the like for facilitating the discharge of the plating solution PS. As the plating solution PS is pushed out from the processing container 10 by the inert gas and the pressure inside the processing container 10 increases with the supply of the inert gas, the discharge rate of the plating solution PS from the processing container 10 can be increased, and it is possible to inhibit the plating solution PS from remaining in the processing container 10.

The timing to supply and discharge the plating solution PS can be appropriately adjusted during the plating process of the wafer W, and before and after the plating process. For example, by supplying and discharging the plating solution PS in parallel during the plating process, the plating process may be performed while the plating solution PS in the processing container 10 is circulated. In this case, even after the processing container 10 is filled with the plating solution PS, the gate valve 23g of the plating solution supply unit 23 is not closed and kept open. Meanwhile, at the timing when the processing container 10 is filled with the plating solution PS, the gate valve 33g of the plating solution discharge unit 33 is opened and such a state is maintained. After the plating process is completed, the gate valve 23g is closed, and after the discharge of the plating solution PS from the processing container 10 is completed, the gate valve 33g is closed.

As illustrated in FIG. 4A, after the gate valve 33g of the plating solution discharge unit 33 is closed, the gate valve 22g of the ion-exchange water supply unit 22 is opened, and the ion exchange water PL is supplied into the processing container 10 from which the plating solution PS has been discharged, so that a post-cleaning process is performed on the wafer W and the inside of the processing container 10. At this time, the gate valve 32g may also be opened continuously or intermittently to replace the ion exchange water PL in the processing container 10 a plurality of times.

As a result, the plating solution PS remaining on the surfaces of the wafer W and the processing container 10 and the like is almost completely washed away.

When the content of the processing container 10 is switched from the plating solution PS to the ion exchange water PL, the cycle purge process described above may be performed by using an inert gas. That is, after the plating solution PS is discharged and before the ion exchange water PL is supplied, the cycle purge process of supplying an inert gas such as a nitrogen gas supplied by the nitrogen gas supply unit 21 into the processing container 10 to increase the pressure inside the processing container 10 to the atmospheric pressure or higher, then exhausting the inert gas, and reducing the pressure inside the processing container 10 may be performed once or a plurality of times. Thereafter, the ion exchange water PL is supplied into the processing container 10. The supply of the ion exchange water PL can be started at any timing such as the timing when the pressure inside the processing container 10 is equal to or higher than the atmospheric pressure or the timing when the pressure is reduced. When the ion exchange water PL is supplied at the timing when the pressure inside the processing container 10 is reduced, the supply rate of the ion exchange water PL into the processing container 10 can be increased, as in the case of supplying the ion exchange water PL in pre-cleaning described above.

As illustrated in FIG. 4B, after the gate valve 22g of the ion-exchange water supply unit 22 is closed, the gate valve 32g of the ion-exchange water discharge unit 32 is opened, and the ion exchange water PL is discharged from the processing container 10 in which the post-cleaning process is completed. At this time, the ion exchange water PL may be discharged while the inert gas is supplied into the processing container 10. The inert gas may be a nitrogen gas or the like supplied by the nitrogen gas supply unit 21. When the nitrogen gas supply unit 21 is configured to be capable of switching and supplying a plurality of types of gases, the inert gas described above may be a dedicated gas or the like for facilitating the discharge of the ion exchange water PL. As the ion exchange water PL is pushed out from the processing container 10 by the inert gas and the pressure inside the processing container 10 increases with the supply of the inert gas, the discharge rate of the ion exchange water PL from the processing container 10 can be increased, and it is possible to inhibit the ion exchange water PL from remaining in the processing container 10.

Further, in a case where the ion-exchange water discharge unit 32 includes a pump or the like provided in the discharge pipe 32d as described above, when at least one of the ion exchange water PL used for the pre-cleaning or the ion exchange water PL used for the post-cleaning is discharged from the processing container 10, the pump described above may be operated to suck the ion exchange water PL to facilitate the discharge of the ion exchange water PL from the processing container 10.

As illustrated in FIG. 4C, after the gate valve 32g of the ion-exchange water discharge unit 32 is closed, the gate valves 21g and 31g of the nitrogen gas supply unit 21 and the exhaust unit 31 are opened to supply a nitrogen gas IG into the processing container 10 and at the same time, to discharge the nitrogen gas IG from the processing container 10. By repeating the replacement of the nitrogen gas IG in the processing container 10 a plurality of times, a drying process is performed on the wafer W and the inside of the processing container 10.

As a result, the ion exchange water PL remaining on the surfaces of the wafer W and the processing container 10 is removed, and the wafer W and the inside of the processing container 10 is dried.

Thereafter, the gate valve 31g of the exhaust unit 31 is closed with the gate valve 21g of the nitrogen gas supply unit 21 open, and the processing container 10 in which the drying process is completed is filled with the nitrogen gas IG, so that the pressure inside the processing container 10 returns to the atmospheric pressure.

As illustrated in FIG. 4D, the transport mechanism is driven to move the wafer holding unit 40 holding the wafer W upward and unload the wafer W out of the processing container 10 whose pressure has returned to the atmospheric pressure.

In this way, the operation in the substrate processing apparatus 1 of the embodiment is completed.

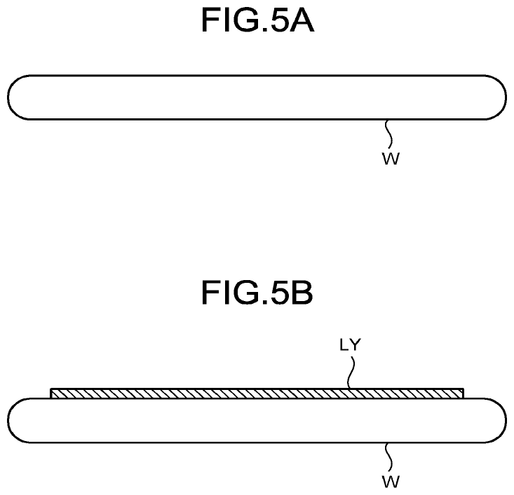

FIGS. 5A and 5B are schematic views illustrating a state where a metal film LY is formed on the wafer W by a plating process performed by the substrate processing apparatus 1 of the embodiment. FIG. 5A illustrates the wafer W before the plating process, and FIG. 5B illustrates the wafer W after the plating process.

As illustrated in FIG. 5B, the metal film LY is formed on the surface of the wafer W on which the semiconductor device is manufactured by the process performed by the substrate processing apparatus 1. By performing various processes on the wafer W thereafter, the semiconductor device including the metal film LY is manufactured.

(Example of Plating Process in Substrate Processing Apparatus)

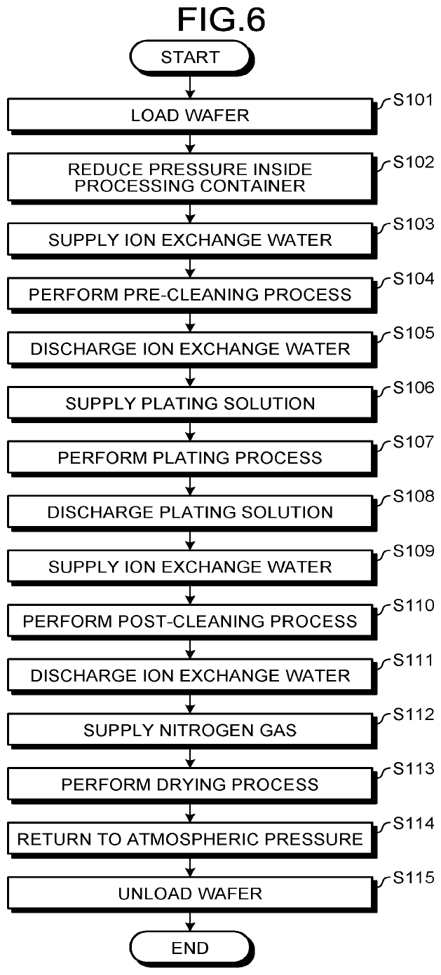

Next, an example of a plating process in the substrate processing apparatus 1 of the embodiment will be described with reference to FIG. 6. FIG. 6 is a flow chart illustrating an example of a procedure of the plating process in the substrate processing apparatus 1 according to the embodiment. The plating process in the substrate processing apparatus 1 is performed as part of the manufacturing process of the semiconductor device.

As illustrated in FIG. 6, the wafer W is loaded into the processing container 10 of the substrate processing apparatus 1 under the atmospheric pressure (step S101). That is, the controller 60 of the substrate processing apparatus 1 controls a suction mechanism included in the wafer holding table 42 of the wafer holding unit 40 to hold the wafer W on the wafer holding table 42. In addition, the controller 60 controls a transport mechanism (not illustrated) to move the wafer holding unit 40 holding the wafer W downward and load the wafer W into the processing container 10.

After the wafer W is loaded into the processing container 10, the controller 60 operates a motor (not illustrated) of the wafer holding unit 40 to start the rotation of the wafer W. The controller 60 continues the rotation of the wafer W until each process in the processing container 10 is completed.

The controller 60 opens the gate valve 31g while operating the pump 31v to exhaust the atmospheric air in the processing container 10 airtightly sealed. As a result, the pressure inside the processing container 10 is reduced (step S102).

The controller 60 opens the gate valve 22g to supply ion exchange water into the processing container 10 with reduced pressure (step S103).

The controller 60 continues to supply the ion exchange water into the processing container 10 to perform a pre-cleaning process on the wafer W and the inside of the processing container 10 (step S104). At this time, the controller 60 may open the gate valve 32g continuously or intermittently to replace the ion exchange water in the processing container 10 a plurality of times.

The controller 60 closes the gate valve 22g and opens the gate valve 32g to discharge the ion exchange water in the processing container 10 in which the pre-cleaning process is completed (step S105).

The controller 60 closes the gate valve 32g and opens the gate valve 23g to supply a plating solution into the processing container 10 from which the ion exchange water has been discharged (step 106).

The controller 60 closes the gate valve 23g, operates a charge supply mechanism (not illustrated) of the wafer holding unit 40, and starts power supply to the wafer W via the contact ring 43 to perform the plating process on the wafer W (step S107).

After the plating process is completed, the controller 60 stops the charge supply mechanism (not illustrated) of the wafer holding unit 40 to stop the power supply to the wafer W.

The controller 60 opens the gate valve 33g to discharge the plating solution in the processing container 10 in which the plating process is completed (step S108).

The controller 60 closes the gate valve 33g and opens the gate valve 22g to supply ion exchange water into the processing container 10 from which the plating solution has been discharged (step S109).

The controller 60 continues to supply the ion exchange water into the processing container 10 to perform a post-cleaning process on the wafer W and the inside of the processing container 10 (step S110). At this time, the controller 60 may open the gate valve 32g continuously or intermittently to replace the ion exchange water in the processing container 10 a plurality of times.

The controller 60 closes the gate valve 22g and opens the gate valve 32g to discharge the ion exchange water in the processing container 10 in which the post-cleaning process is completed (step S111).

The controller 60 closes the gate valve 32g and opens the gate valves 21g and 31g to supply a nitrogen gas into the processing container 10 from which the ion exchange water has been discharged (step S112).

The controller 60 continues to supply the nitrogen gas into the processing container 10 to perform a drying process on the wafer W and the inside of the processing container 10 (step S113).

After the drying process is completed, the controller 60 stops the motor (not illustrated) of the wafer holding unit 40 to stop the rotation of the wafer W.

The controller 60 closes the gate valve 31g with the gate valve 21g open and fills the processing container 10 with the nitrogen gas to return the pressure inside the processing container 10 to the atmospheric pressure (step S114).

The controller 60 controls the transport mechanism (not illustrated) to move the wafer holding unit 40 upward and unload the wafer W out of the processing container 10 (step S115).

In this way, the plating process in the substrate processing apparatus 1 of the embodiment is completed.

(Comparison Example)

In some cases, in the manufacturing process of a semiconductor device, the plating process is performed by immersing a wafer in a plating solution filled in a processing container. However, the processing container included in a substrate processing apparatus of a comparative example is open to the atmospheric air, and thus the plating solution may be degenerated and deteriorated by oxidation. As a result, the performance of the plating process using the plating solution may be degraded.

Further, since the plating solution is exposed to the atmospheric air, impurities and foreign substances in the atmospheric air may be mixed in the plating solution. Since the wafer is in contact with the atmospheric air when the wafer is loaded into the processing container, impurities and foreign substances may be brought into the plating solution in the processing container by the wafer. If the plating solution contains impurities and foreign substances, voids may be generated at the interface between a metal film formed by the plating process and another film, and the metal film may be peeled off.

According to the method of manufacturing a semiconductor device of the embodiment, the plating solution is supplied into the processing container 10 under reduced pressure to perform the plating process on the wafer W, and after the plating solution is discharged from the processing container 10, the wafer W is unloaded out of the processing container 10. As a result, it is possible to prevent the plating solution from being exposed to the atmospheric air as much as possible, inhibit the plating solution from being degenerated and deteriorated due to oxidation, and inhibit impurities and foreign substances from being mixed in the plating solution.

According to the method of manufacturing a semiconductor device of the embodiment, ion exchange water is supplied into the processing container 10 before and after the plating process to perform a pre-cleaning process and a post-cleaning process. By performing the pre-cleaning process, it is possible to remove impurities and foreign substances adhering to the wafer W itself, as well as impurities and foreign substances brought into the processing container 10, and to further inhibit impurities and foreign substances from being mixed in the plating solution. By performing the post-cleaning process, it is possible to wash away the plating solution remaining in the wafer W and the processing container 10, to inhibit the plating solution from being oxidized by the subsequent exposure to the atmospheric air, and to inhibit the plating solution oxidized from being mixed again in the tank 53 and the like.

The substrate processing apparatus 1 according to the embodiment includes the processing container 10 that houses the wafer W in the airtightly sealed inside and performs a plating process, and the exhaust unit 31, the plating solution supply unit 23, and the plating solution discharge unit 33 that are connected to the processing container 10. As a result, it is possible to achieve the substrate processing apparatus 1 that can prevent the plating solution from being exposed to the atmospheric air as much as possible, inhibit the plating solution from being degenerated and deteriorated due to oxidation, and inhibit impurities and foreign substances from being mixed in the plating solution.

(Specific Example of Configuration of Substrate Processing Apparatus)

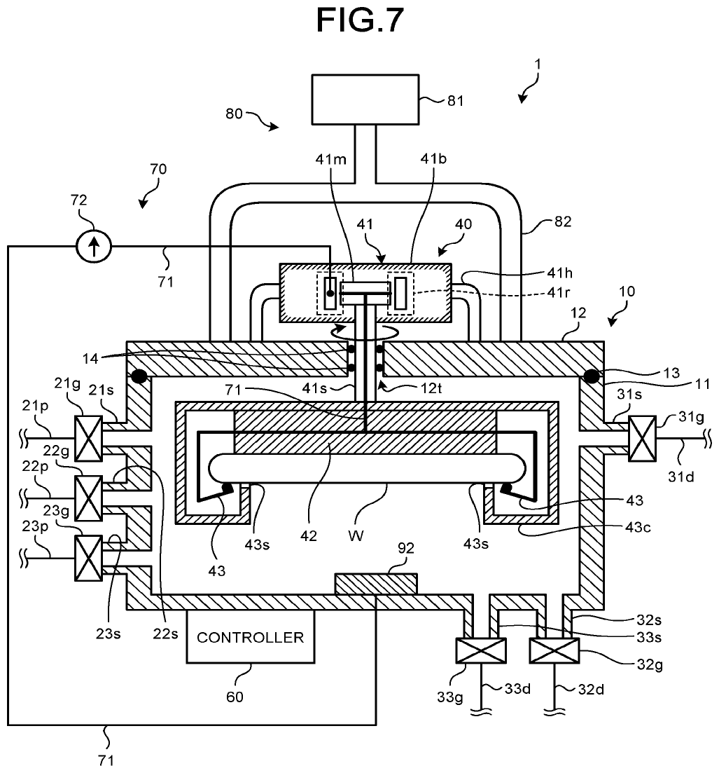

Here, a specific example of the substrate processing apparatus 1 of the embodiment described above is illustrated in FIG. 7. FIG. 7 is a diagram illustrating an example of a more detailed configuration of the substrate processing apparatus 1 according to the embodiment.

That is, FIG. 7 illustrate an example of the substrate processing apparatus 1 that is substantially the same as the one illustrated in FIG. 1 described above, and illustrates an example of a more specific configuration of each part. However, some configurations of the nitrogen gas supply unit 21, the ion-exchange water supply unit 22, the plating solution supply unit 23, the exhaust unit 31, the ion-exchange water discharge unit 32, and the plating solution discharge unit 33 are omitted in FIG. 7. A specific example of the configuration of each part that is not illustrated in FIG. 1 will be described below.

As illustrated in FIG. 7, the wafer holding unit 40 as a substrate holding unit includes the base 41, the wafer holding table 42, and the contact ring 43, as described above.

The base 41 includes a housing 41b, a motor 41m, a rotary connector 41r, a support shaft 41s, and a harness 41h. The housing 41b is disposed above the top plate 12 of the processing container 10, and is installed above the top plate 12 by the harness 41h. The motor 41m and the rotary connector 41r are housed in the housing 41b.

The motor 41m as a rotation mechanism includes a rotor, and rotates the wafer holding table 42 via the support shaft 41s connected to the surface of the wafer holding table 42 on the side of the top plate 12. The support shaft 41s has a hollow columnar shape, and connects the rotor of the motor 41m and the wafer holding table 42 with the top plate 12 interposed therebetween.

The top plate 12 as a lid includes a hole 12t through which the support shaft 41s passes. One or a plurality of O-rings 14 are interposed on the inner wall surface of the hole 12t that is in contact with the support shaft 41s, so that the joint surface between the support shaft 41s and the hole 12t is airtightly sealed. The inner wall surface of the hole 12t may be further coated with a lubricant such as grease (not illustrated). As a result, the airtightness at the joint surface between the support shaft 41s and the hole 12t can be further improved.

The rotary connector 41r as a charge transmission unit is arranged at the outer peripheral end of the motor 41m and at a position surrounding the outer peripheral end of the motor 41m, and is configured to be capable of supplying charges from the outside to the wafer W rotating in synchronization with the motor 41m. Specifically, the rotary connector 41r is a slip ring or the like that includes a brush-like member that is supplied with charges from the outside and comes into contact with the outer peripheral end of the motor 41m. It may be configured that the rotary connector 41r includes a magnetic material or the like that generates a magnetic field in response to an alternating current supplied from the outside and supplies charges to the motor 41m in a non-contact manner. In this case, the substrate processing apparatus 1 further includes an AC/DC converter.

Charges are supplied to the rotary connector 41r by a charge supply mechanism 70. The charge supply mechanism 70 includes an electric wire 71 and a power supply 72. The rotary connector 41r may be included in the charge supply mechanism 70.

The electric wire 71 includes the electric wire 71 that connects the power supply 72 to the contact ring 43, from the power supply 72, via the rotary connector 41r, the motor 41m, the support shaft 41s, and the wafer holding table 42, and the electric wire 71 that connects the power supply 72 to an anode electrode 92. The anode electrode 92 is disposed, for example, at the bottom of the wafer housing unit 11 so as to face the surface of the wafer W, and functions as a metal supply source in the plating process.

In some cases, the electric wire 71 that passes through the inside of the support shaft 41s and the inside of the wafer holding table 42 is referred to as a support rod of the contact ring 43. As described above, the contact ring 43 in contact with the surface of the wafer W supplies charges to the wafer W from the power supply 72.

The contact ring 43 is covered by a contact ring cover 43s. The contact ring cover 43s is disposed on the upper surface side of the wafer holding table 42, that is, on the surface opposite to the side where the wafer W is held, and is configured to surround the entire contact ring 43 that projects from the side surface of the wafer holding table 42 and extends toward the surface of the wafer W. A sealing member 43c made of a resin such as Teflon is interposed on the contact surface of the contact ring cover 43s and the wafer W. As a result, the space in which the contact ring 43 is arranged is airtightly sealed by the contact ring cover 43s while the wafer W is held on the wafer holding table 42.

As described above, the wafer W is passed to the wafer holding table 42 on the upper outer side of the wafer housing unit 11. Consequently, even after the wafer holding table 42 holding the wafer W is immersed in a plating solution in the wafer housing unit 11, the space where the contact ring 43 is arranged is filled with the outside air, and thus it is possible to inhibit the contact ring 43 from being in contact with the plating solution.

As described above, the wafer W held on the wafer holding table 42 is loaded into and unloaded out of the wafer housing unit 11 by a transport mechanism 80. The transport mechanism 80 includes a drive device 81 and a harness 82. The drive device 81 is configured to be capable of vertically moving the harness 82. Alternatively, it may be configured that the harness 82 is vertically movable by vertically moving the drive device 81 itself that is supported to be vertically movable by an adjacent fixing member. The harness 82 is connected to the upper surface of the top plate 12.

When the drive device 81 vertically moves the harness 82 in this way, the top plate 12 to which the harness 82 is connected, the base 41 of the wafer holding unit 40, the base 41 being connected to the top plate 12 via the harness 41h, and the wafer holding table 42 are vertically moved with the movement of harness 82. As a result, the wafer W held by the wafer holding table 42 is loaded into and unloaded out of the wafer housing unit 11.

However, the configuration of the transport mechanism 80 that loads and unloads the wafer W into and out of the processing container 10 is not limited to the example illustrated in FIG. 7. For example, the wafer holding unit 40 may be connected to a drive device that is different from the drive device 81 that vertically moves the top plate 12. In this case, the wafer holding unit 40 does not need to be connected to the top plate 12 by the harness 41h or the like, and may be configured to be vertically moved separately from the top plate 12 by a drive device connected to the wafer holding unit 40. At this time, the vertical movements of the wafer holding unit 40 and the top plate 12 do not necessarily need to be synchronized, and as the wafer holding unit 40 vertically moves after the top plate 12 is opened by the drive device 81, the wafer W may be loaded into and unloaded out of the processing container 10.

Further, the discharge port 32s of the ion-exchange water discharge unit 32 and the discharge port 33s of the plating solution discharge unit 33 may be provided on the bottom surface of the processing container 10 instead of the side surface of the processing container 10 illustrated in the example of FIG. 1. As a result, ion exchange water and a plating solution can be more easily discharged, and it is possible to inhibit a solution from remaining in the processing container 10 after these solutions are discharged.

In the embodiment described above, the pre-cleaning process and the post-cleaning process that use ion exchange water, and the drying process using a nitrogen gas are performed before and after the plating process, but these processes are not essential. Further, rinse solutions used for the pre-cleaning process and the post-cleaning process may be different from each other.

Further, in the embodiment described above, the process performed on the wafer W by the substrate processing apparatus 1 is the plating process, but the process performed by the substrate processing apparatus is not limited to this. The process performed by the substrate processing apparatus may be a cleaning process for the wafer W using, for example, an acidic solution, an alkaline solution, ozone water, or the like. The cleaning process in the substrate processing apparatus is also performed as part of the manufacturing process of a semiconductor device. Even when the cleaning process is performed by the substrate processing apparatus, it is preferable to perform the pre-cleaning process and the post-cleaning process that use ion exchange water or the like before and after the cleaning process.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, the method comprising:
loading a substrate into a processing container;
airtightly sealing the processing container in which the substrate has been loaded;
reducing a pressure of the processing container airtightly sealed;
supplying a processing solution into the processing container with reduced pressure;
performing a process on the substrate using the processing solution;
discharging the processing solution used for the process from the processing container;
after discharging the processing solution, opening the processing container; and
unloading the substrate subjected to the process out of the processing container.

2. The method of manufacturing a semiconductor device according to claim 1,
wherein the process is at least one of a plating process or a cleaning process.

3. The method of manufacturing a semiconductor device according to claim 1,
wherein the process is a plating process, further comprising
before the processing solution is supplied, supplying a first rinse solution into the processing container to perform a cleaning process on the substrate.

4. The method of manufacturing a semiconductor device according to claim 3, further comprising
after performing the cleaning process on the substrate using the first rinse solution and before supplying the processing solution, performing a cycle purge process of supplying an inert gas into the processing container to increase a pressure inside the processing container to an atmospheric pressure or higher, then exhausting the inert gas, and reducing the pressure inside the processing container a predetermined number of times.

5. The method of manufacturing a semiconductor device according to claim 1,
wherein the process is a plating process, further comprising
after the process, supplying a second rinse solution into the processing container to perform a cleaning process on the substrate.

6. The method of manufacturing a semiconductor device according to claim 1,
wherein the process is a plating process, further comprising
after the processing solution is discharged, circulating the processing solution to be supplied again into the processing container.

7. The method of manufacturing a semiconductor device according to claim 6, wherein
supplying the processing solution into the processing container;
discharging the processing solution from the processing container;
performing the process on the substrate using the processing solution; and
while performing the processing solution supply, the processing solution discharge, and the process on the substrate above in parallel, circulating the processing solution to supply the processing solution into the processing container again.

8. The method of manufacturing a semiconductor device according to claim 1, further comprising
after discharging the processing solution and before opening the processing container, supplying an inert gas into the processing container.

9. The method of manufacturing a semiconductor device according to claim 8,
wherein supplying the inert gas into the processing container includes
supplying the inert gas into the processing container to set a pressure inside the processing container to an atmospheric pressure.

10. The method of manufacturing a semiconductor device according to claim 1, wherein
when discharging the processing solution from the processing container, supplying an inert gas into the processing container parallel to discharge the processing solution.

11. The method of manufacturing a semiconductor device according to claim 1, further comprising:
after reducing a pressure inside the processing container airtightly sealed and before supplying the processing solution to the processing container, supplying an inert gas into the processing container; and
when supplying the processing solution into the processing container, exhausting a gas from the processing container parallel to supply the processing solution.

12. The method of manufacturing a semiconductor device according to claim 11,
wherein supplying the inert gas into the processing container includes
supplying the inert gas into the processing container to set a pressure inside the processing container to an atmospheric pressure.

13. A substrate processing apparatus comprising:
a substrate housing unit;
a lid that is connected to the substrate housing unit via a sealing unit to form a processing container capable of being airtightly sealed;
a substrate holding unit that is capable of holding a substrate in the processing container;
a first opening that is provided in the processing container to supply an inert gas into the processing container;
a second opening that is provided in the processing container to supply a rinse solution into the processing container;
a third opening that is provided in the processing container to supply a processing solution into the processing container;
a fourth opening that is provided in the processing container to exhaust a gas in the processing container;
a fifth opening that is provided in the processing container to discharge the rinse solution from the processing container; and
a sixth opening that is provided in the processing container to discharge the processing solution from the processing container.

14. The substrate processing apparatus according to claim 13, further comprising
a controller that controls a first to sixth valves connected to the first to sixth openings, respectively,
wherein the controller
opens the fourth valve to exhaust a gas in the processing container airtightly sealed and reduces a pressure inside the processing container,
opens the second valve to supply the rinse solution into the processing container under reduced pressure,
opens the fifth valve to discharge the rinse solution from the processing container,
opens the third valve to supply the processing solution into the processing container from which the rinse solution has been discharged,
performs a process on the substrate with the processing solution supplied,
after the process on the substrate is completed, opens the sixth valve to discharge the processing solution from the processing container,
opens the second valve to supply the rinse solution into the processing container from which the processing solution has been discharged,
opens the fifth valve to discharge the rinse solution from the processing container, and
opens the first valve to supply the inert gas into the processing container from which the rinse solution has been discharged.

15. The substrate processing apparatus according to claim 14,
wherein the controller
before opening the fourth valve to reduce a pressure of the processing container, loads the substrate into the processing container, and
after opening the first valve to supply the inert gas into the processing container, unloads the substrate out of the processing container.

16. The substrate processing apparatus according to claim 14,
wherein at least before opening the sixth valve to discharge the processing solution, the controller closes the third valve to stop supply of the processing solution into the processing container.

17. The substrate processing apparatus according to claim 13, further comprising
a circulation mechanism that circulates the processing solution discharged from the sixth opening to the third opening.

18. The substrate processing apparatus according to claim 13, further comprising
a rotation mechanism that rotates the substrate holding unit in the processing container airtightly sealed.

19. The substrate processing apparatus according to claim 18, further comprising
a power supply that supplies charges from outside of the processing container to the substrate that is held by the substrate holding unit that is rotating,
wherein the charges are supplied from the power supply to the substrate via a charge transmission unit.

20. The substrate processing apparatus according to claim 19,
wherein the charge transmission unit is a slip ring or a magnetic material.
